(19) United States
(12) Patent Application Publication
(10) Pub. No.: US 2003/0038344 A1
(43) Pub. Date: Feb. 27, 2003

(54) Through-via vertical interconnects, through-via heat sinks and associated fabrication methods

(75) Inventors: William Devereux Palmer, Durham, NC (US); Salvatore Bonafede, Durham, NC (US); Dorota Temple, Cary, NC (US); Brian Stoner, Chapel Hill, NC (US)

Correspondence Address: ALSTON & BIRD LLP, BANK OF AMERICA PLAZA, 101 SOUTH TRYON STREET, SUITE 4000, CHARLOTTE, NC, 28280-4000, US

(73) Assignee: MCNC, Research Triangle Park, NC

(21) Appl. No.: 10/227,089

(22) Filed: Aug. 23, 2002

Related U.S. Application Data
(60) Provisional application No. 60/315,009, filed on Aug. 24, 2001.

(51) Int. Cl. H01L 29/40

(52) U.S. Cl. 257/621

(57) ABSTRACT

An improved through-via vertical interconnect, through-via heat sinks and associated fabrication techniques are provided for. The devices benefit from an organic dielectric layer that allows for low-temperature deposition processing. The low-temperature processing used to form the through-via interconnects and heat sinks allows for the formation of the interconnects and heat sinks at any point in the fabrication of the semiconductor device, including post-formation of active devices and associated circuitry. The through-via vertical interconnects of the present invention are fabricated so as to insure conformal thickness of the various layers that form the interconnect constructs. As such, the interconnects can be formed with a high aspect ratio, in the range of about 4:1 to about 10:1, substrate thickness to interconnect diameter.

### CROSS-REFERENCE TO RELATED APPLICATIONS

The present application claims priority from U.S. Provisional Patent Application Serial No. 60/315,009, filed Aug. 24, 2001, the contents of which are incorporated by reference.

### FIELD OF THE INVENTION

The present invention relates to semiconductor devices, and more particularly to through-via vertical interconnects and through-via heat sinks and related methods for fabricating the same.

### BACKGROUND OF THE INVENTION

At the advent of the semiconductor industry, substrate-to-substrate electrical and electro-optic interconnections were limited to connecting devices by wire bond techniques. This meant that in most instances, the substrates existed in a linear, two-dimensional orientation with wires connecting the desired devices. The advent of through-via interconnects (i.e., connections made from one side of the substrate through to the opposite side of the substrate) has led to stacked configurations of substrates that exist in a three-dimensional relationship. These stacked configurations provide for a more compact packaging design and allow for fabrication of high-density devices, such as sensor or transducer arrays.

Additionally, through-via interconnects provide for interconnections between different series of devices. For example, analog devices, such as transistors or the like may be fabricated on one substrate while digital devices, such as data processing components may be fabricated on a second substrate. Cost constraints and fabrication concerns make it impractical to combine the analog and digital devices on a single substrate. Thus, through-via interconnects provide a means for connecting dissimilar devices in a dense, stacked packaging environment.

Typically, through-via interconnects are fabricated using some level of high temperature processing. For instance, dielectric layers in the form of oxides are typically formed by a thermal oxidation process that occurs at temperatures in excess of 1000° C. Such high temperature processing limits the formation of the through-via interconnects to a front-end process (i.e., before devices are formed on the substrate). Most devices subsequently formed on the substrate would be negatively impacted from a functionality and reliability perspective if they were to be subject to such high temperature processing at the back-end of the overall fabrication process.

Back-end processing of the through-via interconnects is desirable due to the manner in which substrate processing and device fabrication are typically undertaken. In many applications, devices are formed on a thick substrate and then a significant portion of the backside of the substrate is etched away as a means of thinning the substrate post device formation. Forming the through-via interconnects prior to the substrate etch processing would be impractical because the aspect ratios of the vias would be so high that conformal deposition within the via walls could not be achieved. Thus, the need exists in many applications to form the vias at the back-end of the process, after the devices have already been formed on the substrate and backside etching processes have ensued.

To date, low temperature processing of through-via interconnects has been limited to such fabrication techniques as plasma-enhanced chemical vapor deposition (PECVD). However, PECVD and other known low temperature processes do not provide for conformal deposition within the interior walls of the through-via. In general, these processes are not able to provide conformal deposition to vias having high aspect ratios of 3:1, 4:1 or 5:1 (height of via to diameter of via). Conformal coverage of the walls of the via is required for further fabrication of the interconnect and insures proper electrical or optical signal transmission through the resulting interconnect.

Therefore, the need exists to develop a through-via interconnect that provides for low-temperature processing and conformal deposition within high aspect ratios. The low-temperature processing will allow the through-via interconnects to be formed at the back-end of the overall semiconductor device processing flow.

### SUMMARY OF THE INVENTION

The present invention provides for improved through-via vertical interconnects and through-via heat sinks. The devices benefit from an organic dielectric layer that allows for low-temperature deposition processing. The low-temperature processing used to form the through-via interconnects and heat sinks allows for the formation of the interconnects and heat sinks at any point in the fabrication of the semiconductor device, including post-formation of active devices and associated circuitry. The through-via vertical interconnects of the present invention are fabricated so as to insure conformal thickness of the various layers that form the interconnect constructs. As such, the interconnects can be formed with a high aspect ratio, in the range of about 10:1, substrate thickness to interconnect diameter.

The invention is embodied in a through-via vertical interconnect device. The device comprises a substrate having at least one via formed therein, an organic dielectric layer disposed on the surface of the at least one via, and a first conductive layer disposed on the dielectric layer that forms a through-via vertical interconnect between a first generally planar surface of the substrate and a second generally planar surface of the substrate. In one preferred embodiment, the organic dielectric material comprises a parylene material such as Parylene C, N or D.

In many embodiments of the device, the dielectric layer and first interconnect layer are disposed while the substrate is held at a temperature of less than about 300 degrees Celsius. This low temperature processing allows for the interconnects to be formed at the back-end of the manufacturing process, after active devices and electrical circuitry have been formed on the substrate.

Additionally, the device may comprise a diffusion barrier layer disposed on the surface of the at least one via between the dielectric layer and the first conductive layer and an adhesion-promoting device disposed between the first conductive layer and the layer adjacent to the first conductive layer. In most embodiments the through-via vertical interconnect will include a second conductive layer disposed on the first conductive layer, the second conductive layer serving the purpose of generally filling the at least one via.

In an alternate embodiment of the invention, a method for fabricating through-via vertical interconnects comprises the steps of forming at least one via in a substrate, disposing an organic dielectric layer on the surface of the at least one via and disposing a first conductive interconnect layer on the dielectric layer such that the conductive interconnect layer forms a through-via vertical interconnect between a first generally planar surface of the substrate and a second generally planar surface of the substrate. Additionally, the steps of disposing the organic dielectric and the first conductive layer are accomplished while maintaining the substrate at a temperature of below about 300. The low temperature process is typically maintained by disposing the dielectric layer by vapor phase deposition, such as pyrolytic decomposition coupled with room temperature polymerization and disposing the first conductive interconnect layer by metal-organic chemical vapor deposition (MOCVD) processing. The etch process will typically entail a deep reactive ion etch procedure that provides for vias having a high aspect ratio.

Additionally, the method for fabricating a through-via vertical interconnect may entail additional processing steps. These additional steps include disposing, between the dielectric layer and the first conductive interconnect layer, a diffusion barrier layer on the via surface of the at least one via. The diffusion barrier layer prevents diffusion of metal atoms in high temperature applications. The additional step of disposing an adhesion-promoting layer may be necessary to promote adhesion between the conductive layer and adjacent layers. In most applications it will be necessary to dispose a second conductive interconnect layer on the first conductive interconnect layer such that the second conductive interconnect layer generally fills the at least one via. In these applications the first conductive layer serves as a seed layer for the subsequently formed second conductive layer.

In an alternate embodiment of the invention, a method for semiconductor manufacturing comprises the steps of fabricating active devices and/or electrical circuitry on the surface of a semiconductor substrate. Subsequent to the formation of the active devices and/or electrical circuitry, through-via vertical interconnects are formed in the substrate. Low temperature processing of the through-via vertical interconnects provides for the interconnects to be fabricated after the other structures, circuits and devices have been fabricated on the substrate.

The invention is also embodied in a multi-substrate semiconductor device. The multi-layered semiconductor device will include a stack of two or more substrates. One or more of the substrates in the stack will include one or more through-via vertical interconnects. The one or more through-via vertical interconnects comprising vias formed in the substrate, an organic dielectric layer and a first conductive layer. The through-via vertical interconnects are typically defined by being fabricated while the substrate is held at temperatures below about 300° C. The through-via interconnects serve to electrically connect devices and circuits on one substrate to devices and circuits on another substrate in the stack. The substrates in the stack may be formed all of the same material, e.g., silicon, or the substrates may be formed of dissimilar materials to accommodate electrical and electro-optical connections. Additionally, the multi-substrate device may comprise through-via heat sink structures that provide for a continuous path for heat flow through the entirety of the multiple-substrate semiconductor device.

Thus, the present invention provides for improved through-via vertical interconnects and through-via heat sinks. The low-temperature processing used to form the through-via interconnects and heat sinks allows for the formation of the interconnects and heat sinks at any point in the fabrication of the semiconductor device, including post-formation of active devices and associated circuitry. The through-via vertical interconnects of the present invention are fabricated so as to insure conformal thickness of the various layers that form the interconnect constructs. As such, the interconnects can be formed with a high aspect ratio, in the range of up to about 10:1, substrate thickness to interconnect diameter.

### BRIEF DESCRIPTION OF THE DRAWINGS

FIG. 1 is a cross-sectional view of through-via vertical interconnects in a substrate, in accordance with an embodiment of the present invention.

FIGS. 2A-2D are cross-sectional views of various fabrication stages in the processing of through-via vertical interconnects, in accordance with an embodiment of the present invention.

FIG. 3 is a flow diagram of a process for fabricating through-via vertical interconnects, in accordance with an embodiment of the present invention.

FIG. 4 is a top view perspective of through-via vertical interconnects and through-via heat sink structures, in accordance with an embodiment of the present invention.

FIG. 5 is a cross-sectional diagram of through-via heat sink and through-via vertical interconnect, in accordance with an alternate embodiment of the present invention.

FIG. 6 is a cross-sectional diagram of a multiple-substrate semiconductor device implementing through-via vertical interconnects, through-via heat sinks and adhesive bonding, in accordance with an embodiment of the present invention.

FIG. 7 is a cross-sectional diagram of a multiple-substrate semiconductor device implementing through-via vertical interconnects and solder bumping, in accordance with an embodiment of the present invention.

### DETAILED DESCRIPTION OF THE INVENTION

The present invention now will be described more fully hereinafter with reference to the accompanying drawings, in which preferred embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art. Like numbers refer to like elements throughout.

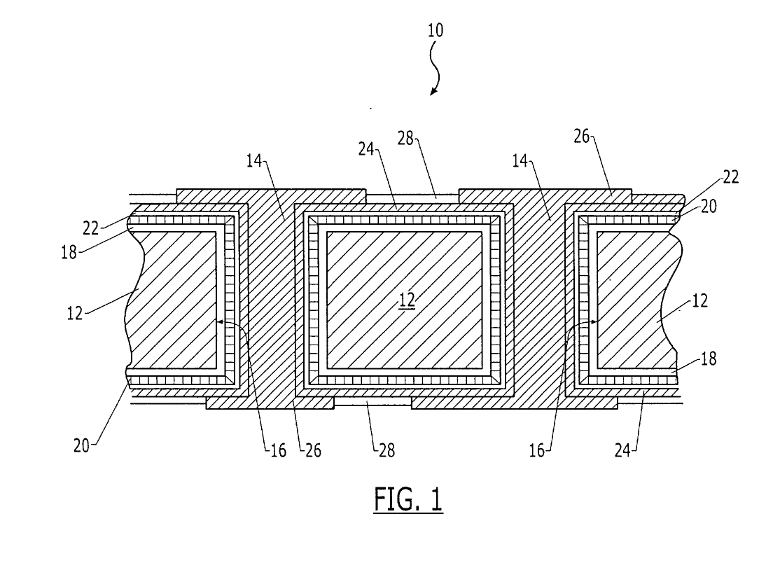

FIG. 1 is a cross sectional diagram of a through-via vertical interconnect (TVI) in accordance with an embodiment of the present invention. The through-via vertical interconnect 10 includes a substrate 12 having one or more vias 14 formed therein. The substrate will typically comprise silicon although any other suitable substrate material may also be used to form the substrate. Examples of other suitable substrate materials include gallium arsenide, ceramic materials, glass materials and the like. The invention provides for vias that can be formed with high aspect ratios, typically in the range of about 4:1 to about 10:1; substrate thickness to via diameter ratio. For example, a 500 micrometer thick substrate will be able to accommodate vias having diameters as small as 50 micrometers. Such high aspect ratios are made possible by the capability of the invention to provide conformal layering of materials within the interior wall 16 of the vias 14.

The surface of the substrate 12 and the interior wall 16 of the one or more vias 14 have disposed thereon an organic dielectric layer 18. In one embodiment of the invention the organic dielectric material will comprise a parylene material, such as Parylene C, N or D. In alternate embodiments, the dielectric layer may be formed of oxides, nitrides or other compounds if a low-temperature (i.e., below 300° C.), conformal deposition technique is implemented. The dielectric layer provides electrical isolation between the substrate and the conductive elements of the one or more though-via vertical interconnects. Typically, the organic dielectric material will be formed by low temperature processing; i.e., processing below about 300 degrees Celsius (° C.), preferably about 200° C. For example, a vapor phase deposition technique, such as pyrolytic decomposition processing coupled with vacuum polymerization, may be used to form the dielectric layer at a temperature of about 200° C. The dielectric layer will typically have a thickness in the range of about 500 angstroms to about 5000 angstroms, preferably about 2000 angstroms.

The through-via vertical interconnect 10 structure may also include optional diffusion barrier layer 20. The diffusion barrier layer is implemented to prevent thermal diffusion of the subsequently formed conductive interconnect material. A diffusion barrier layer will typically be implemented in the through-via vertical interconnect structure if the resulting device is used in a high-temperature application, e.g., a sensor in an automotive application. In low temperature applications it may not be necessary to construct the interconnect of the present invention with a diffusion barrier layer. The diffusion barrier layer is typically disposed using conventional low-temperature CVD or sputtering techniques. The diffusion barrier layer may be formed of a refractory-metal nitride material, such as titanium nitride (TiN). It is also possible to implement other nitride materials, such as silicon nitride (SiNₓ), tantalum nitride (TaN), hafnium nitride (HfN) or the like. The diffusion barrier layer will typically have a thickness in the range of about 500 angstroms to about 5000 angstroms, preferably about 2000 angstroms.

It may also be advantageous to form an optional adhesion-promoting layer 22 between the dielectric layer 18 and the subsequently formed conductive interconnect materials. As is known by those of ordinary skill in the art, many conductive materials such as copper and gold have poor adhesion characteristics and require an adhesion-promoter to insure proper adhesion to adjacent layers in the construct. In those applications that require a diffusion barrier layer 20, the diffusion barrier layer may provide adequate adhesion-promoting characteristics. However, in applications which do not require a diffusion barrier layer or applications in which the diffusion barrier layer does not provide adequate adhesion-promoting characteristics it may be necessary to provide for a separate adhesion-promoting layer. The adhesion-promoting layer may be formed of TiN or any other suitable material. The adhesion promoting layer will typically have a thickness in the range of about 50 angstroms to about 200 angstroms, preferably about 100 angstroms. The adhesion-promoting layer can be formed by sputtering or any other suitable low temperature process.

The through-via vertical interconnect 10 will include a first conductive layer 24 disposed on either the organic dielectric layer 18 or, if required, the diffusion barrier layer 20 or the adhesion-promoting layer 22. For vias having a large diameter the first conductive layer may act as a seed layer for a subsequently formed second conductive layer 26 that fills in the via in its entirety. The first conductive layer is typically formed by a metal-organic chemical vapor deposition (MOCVD) technique or any other suitable low-temperature process. The first conductive layer may comprise copper, gold or any other suitable conductive material. The first conductive layer will typically have a thickness in the range of about 0.5 micrometers to 5 micrometers, preferably about 1 micrometer.

In large via structures it may be necessary to fill the vias in their entirety with an optional second conductive layer 26. The processing of the second conductive layer will typically occur after a masking operation has defined the areas 28 on the surface of the substrate 12 that will form the conductive interconnect contacts leading to active devices (not shown in FIG. 1). The second conductive layer is typically formed by an electrochemical deposition technique or any other suitable low-temperature process. The second conductive layer may comprise copper, gold or any other suitable conductive material and will typically be equivalent to the material used to form the first conductive layer. The thickness of the second conductive layer will generally be dictated by the diameter of the via that requires filling.

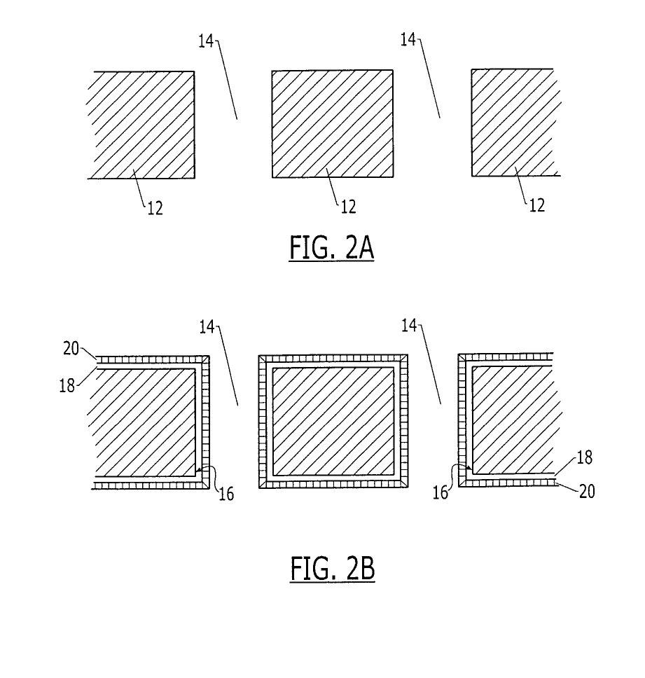

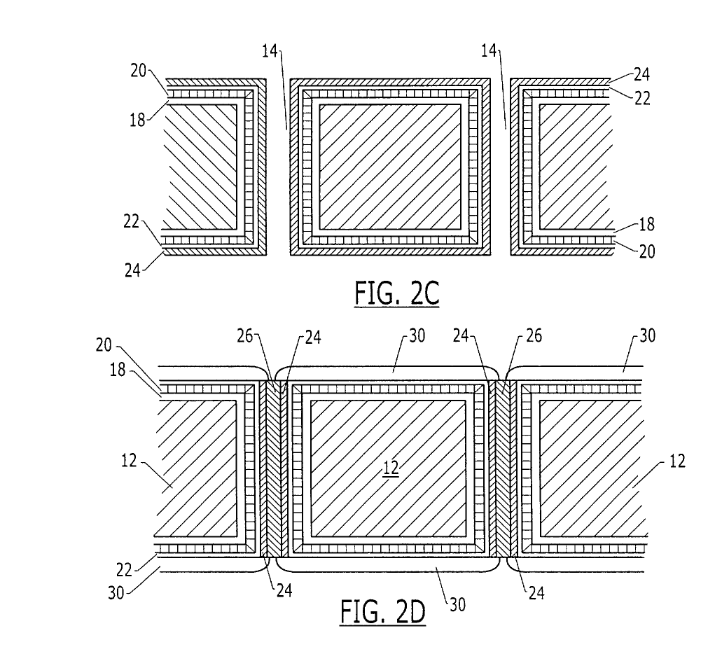

FIGS. 2A-2D are cross-sectional diagrams of various stages in the fabrication process of a through-via vertical interconnect device, in accordance with a method of manufacturing embodiment of the present invention. The fabrication process implements low-temperature processing that allows for through-via vertical interconnects to be formed on the substrate after active devices and circuitry have been fabricated.

FIG. 2A depicts a cross-sectional representation of a substrate 12 having one or more vias 14 formed therein. Typically, photolithographic patterning is used to define and pattern the regions on the substrate where the vias will be formed. Once the patterning defines the regions, an etch process, such as deep reactive-ion etching, is implemented to create high-aspect through substrate vias.

FIG. 2B depicts a cross-sectional representation of the through-via vertical interconnect structure following formation of the dielectric layer 18 and the optional diffusion barrier layer 20. The dielectric layer is disposed by low temperature processing; i.e., processing below about 300 degrees Celsius (° C.), preferably about 200° C. For example, a vapor phase deposition technique, such as pyrolytic decomposition coupled with room temperature polymerization may be used to form the dielectric layer at a temperature of about 200° C. Pyrolytic decomposition involves vaporizing a monomer, heating the vapor to a cracking temperature to break bonds and condensing the products on the surface of the substrate to form a polymer (i.e., surface polymerization). While the vapor in the process exceeds the low temperature threshold of about 300° C., the substrate construct is kept at a low temperature (i.e., typically room temperature) to facilitate the surface polymerization process. The diffusion barrier layer is disposed by a low temperature processing technique, such as metal-organic chemical vapor deposition (MOCVD), ion beam sputtering deposition (IBSD) or a similar deposition process.

FIG. 2C depicts a cross-sectional representation of the through-via vertical interconnect structure following formation of the optional adhesion promoting layer 22 and the first conductive layer 24. The optional adhesion-promoting layer is typically used to promote adhesion between the subsequently formed conductive layer and the dielectric or diffusion barrier layers. The adhesion promoting layer may be disposed by a conventional sputtering technique or any other suitable semiconductor deposition technique may be used. The first conductive layer is disposed using a low temperature processing technique, such as MOCVD, IBSD or a similar semiconductor processing technique. In large diameter vias the first conductive layer forms the seed layer for subsequent processing of the second conductive layer which fills the via in its entirety.

FIG. 2D depicts a cross-sectional diagram of the through-via vertical interconnect structure following formation of the second conductive layer 26, planarization and an optional passivation layer 30. The passivation layer helps to protect the circuitry and devices. The passivation layer may be fabricated from a suitable inorganic or organic material, such as silicon oxide, silicon nitride, silicon oxynitride, polyimide or benzocyclobutene (BCB). The passivation layer will typically have a thickness of about 0.5 micrometers to about 8.0 micrometers.

After the second conductive layer 26 is deposited those areas of the first conductive layer 24 that do not underlie the second conductive layer are removed. Typically a chemical polish process is used to remove those portions of the first conductive layer. The polish process will expose back to either the dielectric layer 18, the diffusion barrier layer 20 or, as shown in FIG. 2D, the adhesion promoting layer 22. Subsequent to the removal/polish processing the optional passivation layer is disposed on the exposed areas of the dielectric layer 18, the diffusion barrier layer 20 or, as shown in FIG. 2D, the adhesion promoting layer 22. Typically, the passivation layer will comprise an organic dielectric material, such as benzocyclobutene (BCB) or an organic dielectric material, such as silicon oxynitride.

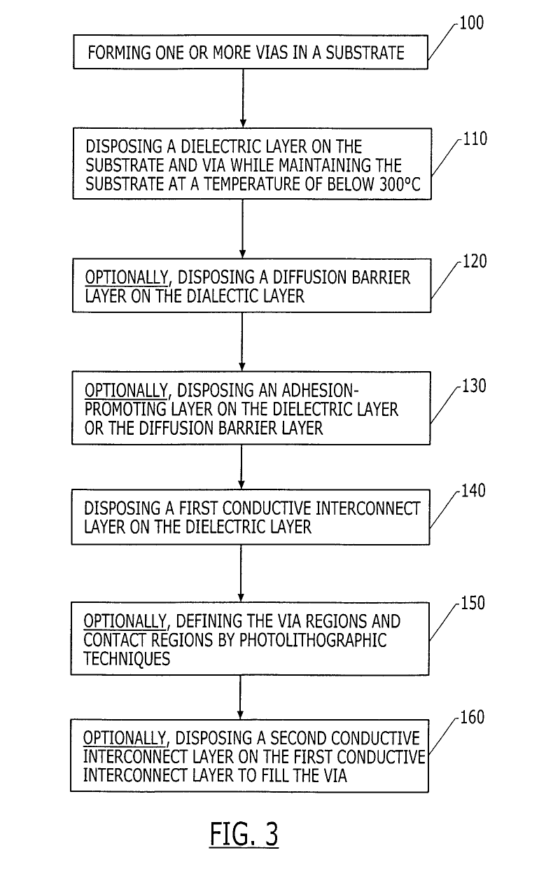

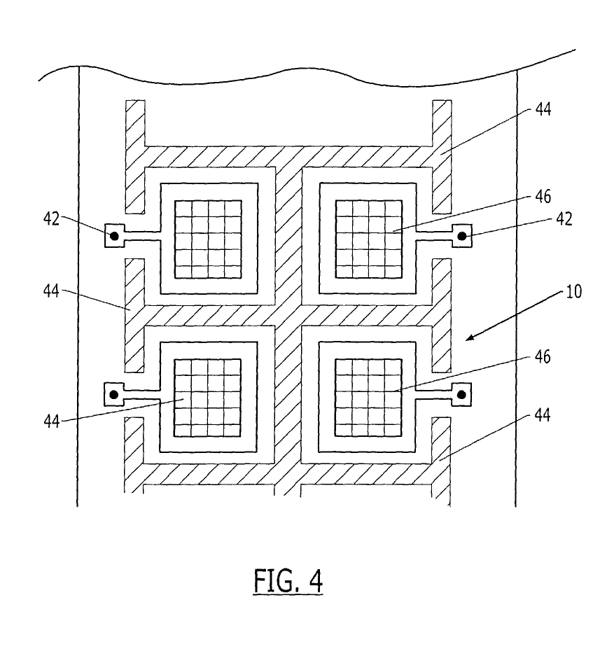

FIG. 3 is a flow diagram of the processing steps implemented to fabricate the through-via vertical interconnect device, in accordance with an embodiment of the present invention. The fabrication process provides for low temperature processing throughout, thus allowing for the vias to be formed after the fabrication of active circuitry on the substrate. At step 100 one or more vias are formed in a substrate, typically an etch process is used to form vias having a high aspect ratio, such as deep reactive-ion etching or the like.

At step 110, an organic dielectric layer is disposed on the substrate and the interior surface of the one or more vias. The dielectric material will typically be disposed by a low temperature process that provides for the substrate to be held at a temperature below about 300 degrees Celsius while the deposition of the organic dielectric layer takes place. For example, pyrolytic decomposition processing may be used whereby a monomer is vaporized, the vapor is heated to a cracking temperature and surface polymerization occurs on the substrate.

At optional step 120, a diffusion barrier layer is disposed on the dielectric layer. The diffusion barrier layer prevents the thermal diffusion of the conductive interconnect material. The diffusion barrier layer will typically be required if the resulting device is implemented in high temperature applications. In low temperature applications, the need to implement a diffusion barrier layer may be obviated. At optional step 130, an adhesion promoting layer is disposed on either the dielectric layer or the diffusion layer. The adhesion-promoting layer may be required to promote adhesion between the dielectric layer or the diffusion barrier layer and the subsequently formed conductive layer. Typically, conductive layer materials, such as copper, gold and the like require an adhesion-promoting layer to sufficiently adhere to the underlying layer. The diffusion barrier layer and the adhesion-promoting layer will typically be disposed by a low temperature process that provides for the substrate to be held at a temperature below about 300 degrees Celsius.

At step 140, the first conductive interconnect layer is disposed on the dielectric layer (or intermediary layers, such as the diffusion barrier layer or the adhesion promoting layer). The first conductive interconnect layer will be disposed such that the conductive interconnect layer forms a through-via electrical interconnect between the first generally planar surface of the substrate and the second generally planar surface of the substrate. The first conductive layer will typically be formed by low temperature processing that provides for the substrate to be held at a temperature below about 300° C. For example the first conductive layer may be formed by MOCVD processing techniques or the like.

At optional steps 150 and 160, lithographic patterning occurs whereby a photoresist is disposed, patterned and masked to define the via regions and the conductive contacts leading from the vias. In instances in which the through-via vertical interconnects have large via diameters, a second conductive layer will be disposed to fill the via in its entirety. The second conductive layer will typically be formed by low temperature processing that provides for the substrate to be held at a temperature below about 300° C. For example the second conductive layer may be formed by conventional electroplating techniques or the like.

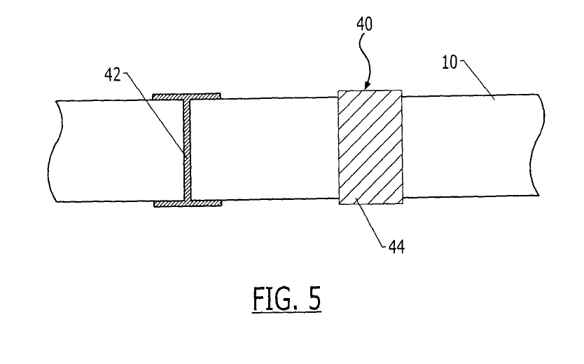

FIG. 4 is a plan view diagram and FIG. 5 is a cross-sectional diagram of a heat sink structure that may be fabricated in unison with the through-via vertical interconnects, in accordance with an alternate embodiment of the present invention. The semiconductor substrate 10 has formed therein one or more heat sink apertures 40. The heat sink aperture may be formed by creating an opening in the substrate using conventional chemical etching or mechanical machining methods. In one embodiment of the invention the aperture is formed by a through-wafer anisotropic chemical etching technique. The heat sink apertures will typically be formed during the same etch process that forms the through-wafer interconnect vias 42, shown in FIG. 4 and FIG. 5.

In the embodiment shown in FIG. 4, the heat sink structure 44 is designed in a multiple-branch configuration to give maximum surface area exposure to the thickness of the substrate. Additionally, the multiple-branch configuration allows for the heat sink structure to surround the one or more power-dissipating semiconductor devices 46 that are formed on the substrate.

Subsequent to the formation of the heat sink apertures 40 in the substrate 10, the apertures are filled with a thermally conductive material, such as a suitable metal material, preferably nickel, copper or the like. Conventional chemical or mechanical deposition techniques are typically used to fill the heat sink apertures with the thermally conductive and form the heat sink structures 44. For example, a conventional electroplating technique may be used to fill the heat sink apertures. In this regard, the filling of the apertures with thermally conductive material may be accomplished by the first and/or second conductive layer process steps used to form the conductive interconnect vias 42.

The heat sink structure will typically be thermally, and characteristically mechanically, connected to an external cooling device, such as a Peltier device or other thermoelectric modules (not shown in FIGS. 1 and 2). The cooling device serves to maintain the metal component of the heat sink at a temperature well below the operating temperature of the electronic device(s) formed on the substrate. By natural conduction, heat will flow from the higher temperature regions, i.e., the power dissipating semiconductor devices 46 to the lower temperature regions, i.e., the through-via heat sink structure. In turn, the heat sink structure conducts the heat to the external cooling device.

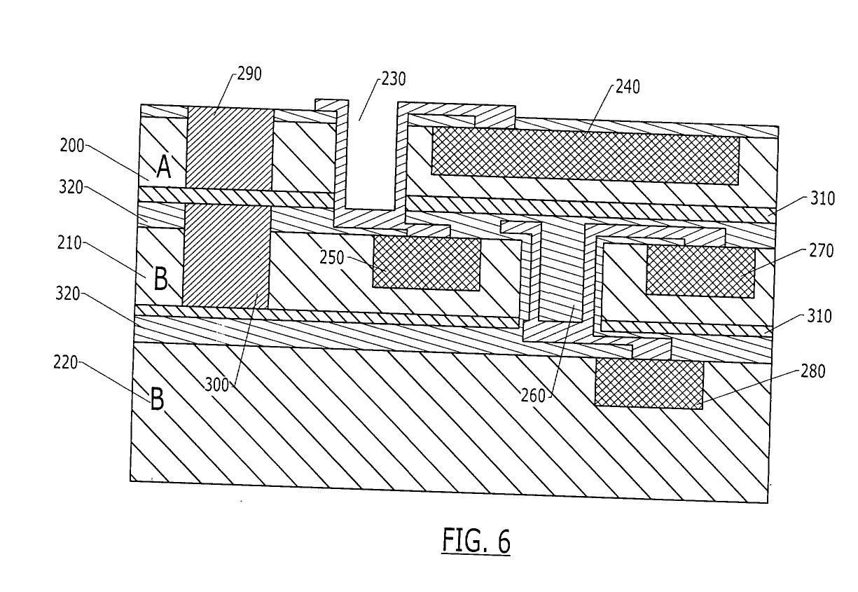

FIG. 6 is a cross-sectional representation of a multiple substrate stack incorporating through-via vertical interconnects and through substrate heat sinks, in accordance with an embodiment of the present invention. The illustrated embodiment comprises three stacked substrates 200, 210 and 220 having active devices, through-via vertical interconnects that connect the active devices and through-via heat sink structures that dissipate the heat in the overall multi-substrate structure. The substrates may be similar materials (i.e., all silicon substrates), thus, providing for homogenous integration. Alternatively, the substrates may be dissimilar materials (i.e., silicon substrates and optical material substrates), thus providing for heterogeneous integration. In the embodiment depicted in FIG. 6 the first substrate 200 comprises a first material and the second and third substrates 210 and 220 comprise a second material that is dissimilar from the first material.

In the illustrated embodiment the first substrate 200 has a through-via vertical interconnect 230 that serves to electrically connect an active device 240 formed in the first substrate to an active device 250 formed in the second substrate 210. For example, the first substrate may have an active device in the form of a sensor or detector and this device is connected, through the via, to an analog device, such as an amplifier, in the second substrate. The second substrate 210 has a through-via vertical interconnect 260 that serves to connect an active device 270 formed in the second substrate to active device 280 formed in the third substrate 220. For example, the second substrate may have an analog device, such as an amplifier and this device is connected, through the via, to a processing or multiplexing device formed in the third substrate.

Additionally, the first substrate 200 has a through-via heat sink 290 that is generally aligned and connected to a heat sink structure 300 formed in the second substrate 210. The generally aligned path provides for a continuous heat flow path to the underlying third substrate 220, and an associated external cooling device (not shown in FIG. 6) and/or an area for heat release. In the embodiment shown the heat sink structures are generally aligned to provide for a continuous path, however, it is also possible to fabricate the heat sink structures or stack the wafers so as to provide for partially aligned or non-aligned configuration of the heat sinks. Typically, the multiple substrate stack embodiment will incorporate through-via heat sink structures that allow for heat flow to an external cooling device (not shown in FIG. 6). The external cooling device may be located on the third substrate 220 or in generally close proximity to the multiple substrate stack.

The individual substrates of the stacked substrate configuration are fabricated individually and subsequently connected to one another by a conventional soldering, an adhesive bonding procedure or other suitable means of connecting adjoining substrates. In the embodiment shown in FIG. 6, an adhesive layer 310 is provided between the first and second substrates and the second and third substrates. The adhesive layer adheres to the backside of the substrates and the passivation layer 320 that is formed on the substrate above the active components, the through-wafer interconnects and the heat sinks.

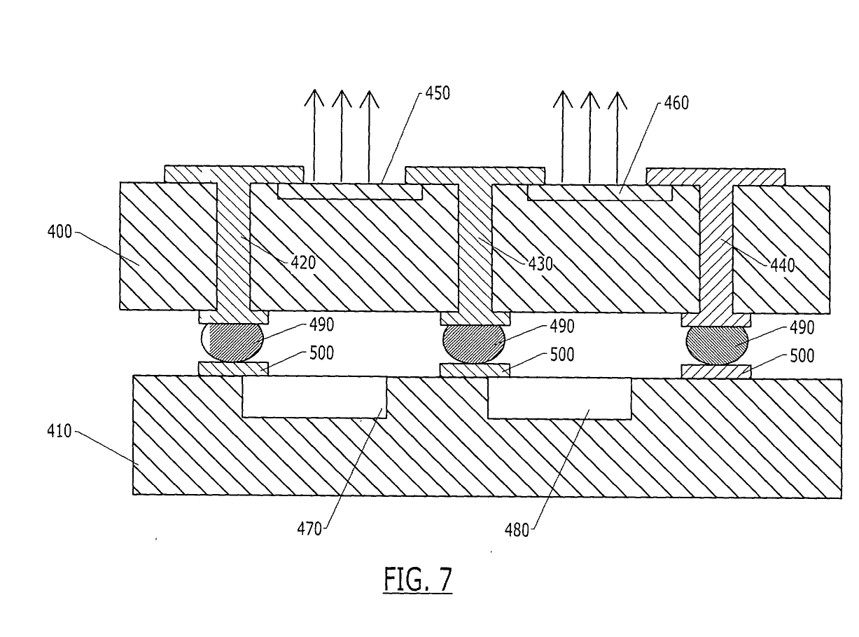

FIG. 7 depicts a cross-sectional representation of a multiple substrate stack incorporating through-via vertical interconnects, in accordance with an embodiment of the present invention. The illustrated embodiment comprises two stacked substrates 400 and 410 having active devices and through-via vertical interconnects that connect the active devices. The first substrate 400 has formed therein three through-via vertical interconnects 420, 430 and 440. The three through-via vertical interconnects provide electrical connection to optoelectronic devices 450 and 460. In one embodiment the first substrate comprises gallium-arsenide (GaAs) and the optoelectronic devices are emissive devices such as vertical cavity surface emitting lasers (VCSELs) or light emitting diodes (LEDs). The VCSELs or LEDs may be disposed in an array formation on the surface of the first substrate. The second substrate 410 has active circuitry 470 and 480 disposed thereon as components in very large scale integration (VLSI) circuitry. In one embodiment the second substrate comprises silicon and the active circuitry devices are sensors. The first and second substrates in the embodiment shown in FIG. 7 are connected via solder bumps 490. The solder bumps are in contact with the through via vertical interconnects 420, 430 and 440 and contact pads 500 formed on the second substrate. Solder bump connections are shown by way of example only, other means of connecting the substrates, such as adhesive bonding or the like, may also be implemented without departing from the inventive concepts herein disclosed. The configuration shown in FIG. 7 provides for a scalable array of optoelectronic devices and eliminates wire bonds and surface leads, thereby, reducing interconnect inductance and capacitance.

Accordingly, the present invention provides for an improved, through-via vertical interconnect, through-via heat sinks and the associated methods for fabricating the interconnects and heat sinks. By incorporating an organic dielectric material, such as a parylene compound, low-temperature processing can be maintained throughout the fabrication process. The low-temperature processing used to form the through-via interconnects and heat sinks allows for the formation of the interconnects and heat sinks at any point in the fabrication of the semiconductor device, including post-formation of active devices and associated circuitry. The through-via vertical interconnects of the present invention are fabricated so as to insure conformal thickness of the various layers that form the interconnect constructs. As such, the interconnects can be formed with a high aspect ratio, in the range of about 4:1 to about 10:1, substrate thickness to interconnect diameter. The interconnects and heat sinks have heightened utility in multiple-substrate constructs. They provide a simple means of electrical connection between stacked substrates, thereby, eliminating unnecessary electrical bond wires and they provide the impetus for stacking substrates of dissimilar material types.

Many modifications and other embodiments of the invention will come to mind to one skilled in the art to which this invention pertains having the benefit of the teachings presented in the foregoing descriptions and the associated drawings. Therefore, it is to be understood that the invention is not to be limited to the specific embodiments disclosed and that modifications and other embodiments are intended to be included within the scope of the appended claims. Although specific terms are employed herein, they are used in a generic and descriptive sense only and not for purposes of limitation.

That which is claimed:

1. A through-via vertical interconnect device, the device comprising:
a substrate having at least one via formed therein, the at least one via defining a via surface that extends from a first generally planar surface of the substrate to a second generally planar surface of the substrate;
an organic dielectric layer disposed on the via surface of the at least one via; and
a first conductive layer disposed on the dielectric layer that forms a through-via vertical interconnect between the first generally planar surface of the substrate and the second generally planar surface of the substrate.

2. The through-via interconnect device of claim 1, wherein the organic dielectric layer further comprises a parylene material.

3. The through-via interconnect device of claim 1, further comprising a diffusion barrier layer disposed on the via surface of the at least one via between the dielectric layer and the first conductive layer.

4. The through-via interconnect device of claim 3, wherein the diffusion barrier layer comprises a nitride material.

5. The through-via interconnect device of claim 1, further comprising a second conductive layer disposed on the first conductive layer, the second conductive layer generally filling the at least one via.

6. The through-via interconnect device of claim 1, wherein the organic dielectric layer and the first conductive layer are disposed while the substrate is held at a temperature of less than about 300 degrees Celsius.

7. A method for fabricating through-via vertical interconnects, the method comprising the steps of:
forming at least one via in a substrate, the at least one via defining a via surface that extends from a first generally planar surface of the substrate to a second generally planar surface of the substrate;
disposing an organic dielectric layer on the via surface of the at least one via;
disposing a first conductive interconnect layer on the dielectric layer such that the conductive interconnect layer forms a through-via electrical interconnect between the first generally planar surface of the substrate and the second generally planar surface of the substrate; and
maintaining the substrate at a temperature of below about 300 degrees while disposing the organic dielectric layer and the first conductive layer.

8. The method of claim 7, wherein the step of disposing a dielectric layer on the via surface of the at least one via further comprises disposing by pyrolytic decomposition processing and room temperature polymerization.

9. The method of claim 7, wherein the step of disposing a first conductive interconnect layer on the dielectric layer further comprises disposing by metal-organic chemical vapor deposition (MOCVD) processing.

10. The method of claim 7, wherein the step of forming at least one via in a substrate further comprises forming, by deep reactive-ion etching, at least one via.

11. The method of claim 7, further comprising the step of disposing, between the dielectric layer and the first conductive interconnect layer, a diffusion barrier layer on the via surface of the at least one via.

12. The method of claim 7, further comprising the step of disposing, previous to disposing the first conductive interconnect layer, an adhesion promoting layer on the via surface of the at least one via.

13. The method of claim 7, further comprising the step of disposing a second conductive interconnect layer on the first conductive interconnect layer such that the second conductive interconnect layer generally fills the at least one via.

14. A through-via vertical interconnect device, the device comprising:
a substrate having at least one via formed therein, the at least one via defining a via surface that extends from a first generally planar surface of the substrate to a second generally planar surface of the substrate;
an organic dielectric layer disposed on the via surface of the at least one via, the organic dielectric layer being disposed while the substrate is held at a temperature of less than about 300 degrees Celsius; and
a first conductive layer disposed on the dielectric layer that forms a through-via vertical interconnect between the first generally planar surface of the substrate and the second generally planar surface of the substrate, the first conductive layer the dielectric layer being disposed while the substrate is held at a temperature of less than about 300 degrees Celsius.

15. The through-via vertical interconnect device of claim 14, wherein the dielectric layer comprises a Parylene material.

16. The through-via vertical interconnect device of claim 14, further comprising a diffusion barrier layer disposed on the via surface of the at least one via between the dielectric layer and the first conductive layer.

17. The through-via vertical interconnect device of claim 16, wherein the diffusion barrier layer comprises a nitride material.

18. The through-via vertical interconnect device of claim 14, further comprising a second conductive layer disposed on the first conductive layer, the second conductive layer generally filling the at least one via.

19. A multi-substrate semiconductor device, the device comprising:
a first substrate having one or more first substrate through-via vertical interconnects formed therein, the first substrate through-via vertical interconnects comprising vias formed in the first substrate, an organic dielectric layer disposed in the via and a first conductive disposed on the organic dielectric layer; and
a second substrate generally underlying the first substrate and affixed to the first substrate, the second substrate having electrical circuitry formed thereon that is in electrical communication with the first substrate by the one or more first substrate through-via vertical interconnects.

20. The multi-substrate semiconductor device of claim 19, wherein the first substrate comprises a first material and the second substrate comprises a second material.

21. The multi-substrate semiconductor device of claim 19, wherein the first and second substrates comprise a first material.

22. The multi-substrate semiconductor device of claim 19, wherein the first substrate is affixed to the second substrate by a substrate bonding technique.

23. The multi-substrate semiconductor device of claim 19, wherein the first substrate is affixed to the second substrate by solder bumps.

24. The multi-substrate semiconductor device of claim 19, wherein the first substrate further comprises a first substrate through-via heat sink structure, the first substrate through-via heat sink structure comprising vias formed in the first substrate, an organic dielectric layer disposed in the via and a first conductive layer disposed on the organic dielectric layer.

25. The multi-substrate semiconductor device of claim 19, further comprising a third substrate generally overlying the first substrate and affixed to the first substrate, the third substrate having one or more third substrate through-via vertical interconnects formed therein.

26. The multi-substrate semiconductor device of claim 25, wherein the first substrate further comprises electrical circuitry and the one or more third substrate through-via vertical interconnects provide electrical communication between the electrical circuitry on the first substrate and the third substrate.

27. The multi-substrate semiconductor device of claim 25, further comprising a third substrate through-via heat sink structure disposed in the third substrate and a first substrate through-via heat sink structure disposed in the first substrate, wherein the first and third substrate through-via heat sink structures provide a continuous path for heat flow through the entirety of the multiple-substrate semiconductor device.
